(19) United States
(12) Patent Application Publication
(10) Pub. No.: US 2013/0021551 A1
(43) Pub. Date: Jan. 24, 2013

(54) IPS LIQUID CRYSTAL DISPLAY PANEL AND METHOD FOR MANUFACTURING THE SAME

(71) Applicants: CHIA-HUA YU, New Taipei (TW); I-fang Wang, Changhua (TW); Feng-weei Kuo, Pingtung (TW); Ko-ruey Jen, Taipei (TW); Guang-shiung Chao, Kaohsiung (TW)

(72) Inventors: CHIA-HUA YU, New Taipei (TW); I-fang Wang, Changhua (TW); Feng-weei Kuo, Pingtung (TW); Ko-ruey Jen, Taipei (TW); Guang-shiung Chao, Kaohsiung (TW)

(73) Assignee: Hannstar Display Corporation, New Taipei City (TW)

(21) Appl. No.: 13/371,391

(22) Filed: Feb. 10, 2012

(30) Foreign Application Priority Data
Jul. 22, 2011 (TW) 100126031

(51) Int. Cl. G02F 1/136; H01L 33/08

(52) U.S. Cl. 349/43; 438/30; 257/E33.012

(57) ABSTRACT

An in-plane switching (IPS) liquid crystal display panel and a method for manufacturing the same are disclosed. The method comprises the following steps: forming gate lines, data lines, common lines, pixel electrodes and common electrodes on a first substrate in sequence, wherein at least a portion of each of the common lines is positioned above each of the gate lines; and forming a liquid crystal layer between the first substrate and a second substrate.

### FIELD OF THE INVENTION

The present invention is related to a liquid crystal display (LCD) panel and a method for manufacturing the same, and more particularly, to an in-plane switching (IPS) liquid crystal display panel and a method for manufacturing the same.

### BACKGROUND OF THE INVENTION

LCDs have been widely applied in electrical products due to the rapid progress of optical and semiconductor technologies. With their advantages of high image quality, compact size, light weight, low driving voltage, low power consumption and various applications, LCDs have been introduced into portable computers, mobile phones, personal digital assistants and color televisions and are becoming the mainstream display apparatus.

Currently, most of LCDs are backlight type LCDs which comprise a liquid crystal panel and a backlight module. In general, the LCD panel may include a color filter (CF) substrate and a thin film transistor (TFT) array substrate. Since the demand on utilizing LC molecule alignments to control light transmissions, the conventional LCD has a disadvantage of an inherently narrowed viewing angle. Especially for a large size LCD, the problem of how to broaden its viewing angle gets more concerned. Presently, an IPS technique has been developed so as to broaden the viewing angle. In the IPS technique, a pixel electrode is parallel to a common electrode for forming an electric field parallel to the substrates. In that manner, the LC molecule can be aligned by the lateral electric field between the pixel electrode and the common electrode for a wide viewing angle and a great color reproduction.

However, in each pixel of a conventional IPS panel, the pixel electrode is connected to a gate line, and the common electrode is connected to a common line. The opaque common line is parallel to the gate line, and the opaque common line and the gate line are disposed on the same plane. Thus, a transparent area in the pixel is reduced by the opaque common line, deteriorating an aperture ratio of the pixel and a transmittance of the conventional IPS panel.

### SUMMARY OF THE INVENTION

Therefore, an aspect of the present invention is to provide an IPS liquid crystal display panel and a method for manufacturing the same for increasing a transparent area of pixels, so as to improve the aperture ratio of the pixels of the display panel.

According to one embodiment of the present invention, the IPS liquid crystal display panel comprises: a first substrate; a plurality of gate lines disposed on the first substrate; a plurality of data lines disposed on the first substrate, wherein the data lines crisscross the gate lines to form a plurality of pixel regions, and the pixel regions include thin film transistors (TFTs) electrically connected to the gate lines and the data lines; a plurality of common lines disposed on the first substrate, wherein at least one portion of each of the common lines is positioned above one of the gate lines; a plurality of pixel electrodes formed on the first substrate and electrically connected to the TFTs; a plurality of common electrodes formed on the first substrate and electrically connected to the common lines; a second substrate; and a liquid crystal layer formed between the first substrate and the second substrate.

In one embodiment of the present invention, the common lines are completely overlapping with the gate lines.

In one embodiment of the present invention, the common lines are overlapping with the gate lines and the data lines.

In one embodiment of the present invention, the common electrodes directly cover and contact the common lines.

In one embodiment of the present invention, a passivation layer is positioned between the gate lines and the common lines.

In one embodiment of the present invention, an over-coating layer is positioned on the passivation layer, and the common lines are positioned on the over-coating layer.

According to another embodiment of the present invention, a method for manufacturing the IPS liquid crystal display panel, comprises the following steps: forming a plurality of gate lines on a first substrate; forming a plurality of data lines on the first substrate, wherein the gate lines and the data lines are crisscrossed to form a plurality of pixel regions arranged in an array, wherein the pixel regions include TFTs electrically connected to the gate lines and the data lines; forming a plurality of common lines on the first substrate, wherein at least one portion of each of the common lines is positioned above one of the gate lines; forming a plurality of pixel electrodes and a plurality of common electrodes formed on the first substrate, wherein the pixel electrodes are electrically connected to the TFTs, and the common electrodes are electrically connected to the common lines; and forming a liquid crystal layer between the first substrate and a second substrate.

In one embodiment of the present invention, when forming the common lines, in each of the pixel regions, the common lines are completely overlapping with the gate lines.

In one embodiment of the present invention, the plurality of pixel electrodes and the plurality of common electrodes are positioned on the same plane.

In one embodiment of the present invention, the plurality of pixel electrodes and the plurality of common electrodes are transparent electrodes.

In one embodiment of the present invention, when forming the common lines, in each of the pixel regions, the common lines are overlapping with the gate lines and the data lines.

In one embodiment of the present invention, when forming the common electrodes, the common electrodes directly cover and contact the common lines.

Therefore, with the use of a design of the common lines of the IPS liquid crystal display panel, the transparent area of each pixel can be increased, thereby improving the aperture ratio of the pixels of the display panel. Moreover, the common lines of the present invention can act as a block matrix structure for improving the light leakage problem of the panel.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1 is a cross-sectional view showing a display panel and a backlight module according to an embodiment of the present invention;

FIG. 2A and FIG. 2B are schematic diagrams showing a pixel region of the IPS liquid crystal display panel according to a first embodiment of the present invention;

FIG. 3 is a cross-sectional view along the cross-sectional line A-A′ shown in FIG. 2A, and Fig;

FIG. 4A, FIG. 4B and FIG. 4C are schematic flow diagrams showing a process for manufacturing the IPS liquid crystal display panel according to the first embodiment of the present invention; and

FIG. 5A and FIG. 5B, schematic diagrams showing a pixel region of the IPS liquid crystal display panel according to a second embodiment of the present invention.

### DETAILED DESCRIPTION OF THE PREFERRED EMBODIMENT

The following embodiments are referring to the accompanying drawings for exemplifying specific implementable embodiments of the present invention. Furthermore, directional terms described by the present invention, such as upper, lower, front, back, left, right, inner, outer, side and etc., are only directions by referring to the accompanying drawings, and thus the used directional terms are used to describe and understand the present invention, but the present invention is not limited thereto.

In the drawings, structure-like elements are labeled with like reference numerals.

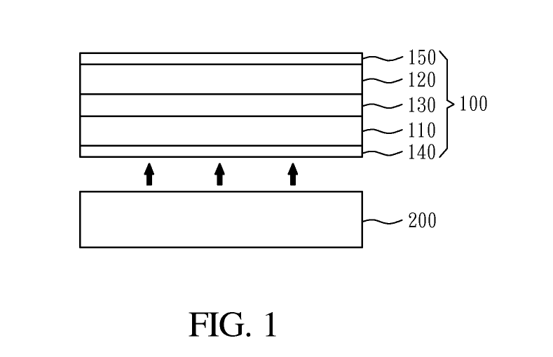

Referring to FIG. 1, a cross-sectional view showing a display panel and a backlight module according to an embodiment of the present invention is illustrated. The IPS liquid crystal display panel 100 of the present embodiment can be disposed opposite to the backlight module 200, thereby forming an IPS liquid crystal display apparatus. The IPS liquid crystal display panel 100 can comprise a first substrate 110, a second substrate 120, a liquid crystal layer 130, a first polarizer 140 and a second polarizer 150. The first substrate 110 and the second substrate 120 may be glass substrates or flexible transparent substrates. In this embodiment, the first substrate 110 may be a thin film transistor (TFT) array substrate, and the second substrate 120 may be a color filter (CF) substrate. It is worth mentioning that the CF and the TFT array may be arranged on the same substrate in other embodiments.

Referring to FIG. 1 again, the liquid crystal layer 130 is formed between the first substrate 110 and the second substrate 120. The first polarizer 140 is disposed on one side of the first substrate 110 and opposite to the liquid crystal layer 130 (as a light-incident side of the first substrate 110). The second polarizer 150 is disposed on one side of the second substrate 120 and opposite to the liquid crystal layer 130 (as a light-emitting side of the second substrate 120).

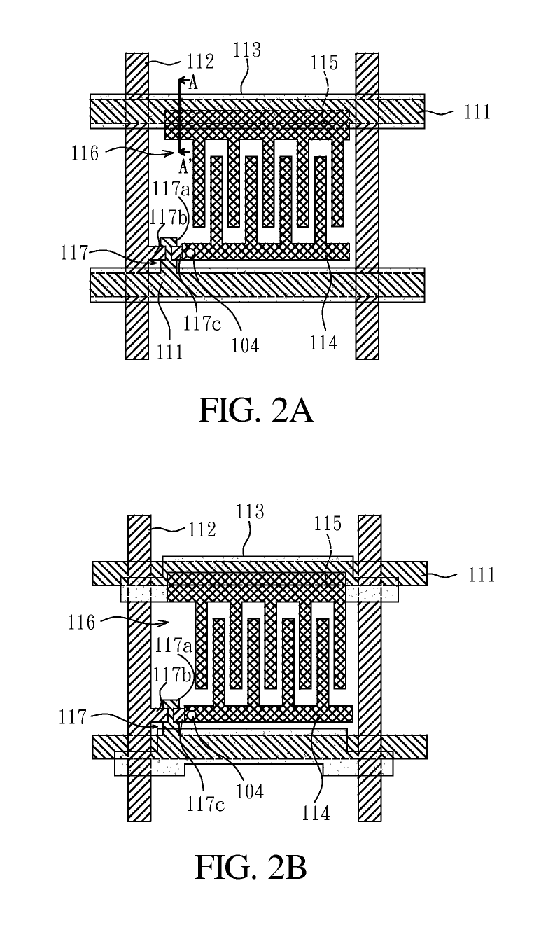

Referring to FIG. 2A and FIG. 2B, schematic diagrams showing a pixel region of the IPS liquid crystal display panel according to a first embodiment of the present invention are illustrated. The IPS liquid crystal display panel 100 further comprises a plurality of gate lines 111, a plurality of data lines 112, a plurality of common lines 113, a plurality of pixel electrodes 114 and a plurality of common electrodes 115. The gate lines 111 and the data lines 112 are crisscrossed on the first substrate 110 and thereby form a plurality of pixel regions 116 arranged in an array. In this case, each of the pixel regions 116 includes at least one TFT 117 electrically connected to the adjacent gate line 111 and the adjacent data line 112. The material of the gate lines 111 may be Al [symbol] Ag [symbol] Cu [symbol] Mo [symbol] Cr [symbol] W [symbol] Ta [symbol] Ti or alloys thereof. The material of data lines 112 may be Mo [symbol] Cr [symbol] Ta [symbol] T or alloys thereof, preferably heat-resistant metal.

Referring to FIG. 2A and FIG. 2B again, the common lines 113 of the present embodiment are disposed on the first substrate 110 and parallel to the gate lines 111, wherein the common lines 113 are electrically Insulated from the first substrate 110. In each of the pixel regions 116, at least one portion of each of the common lines 113 is positioned above one of the gate lines 111, so as to reduce an opaque area in the pixel region 116, thereby increasing an aperture ratio of each of the pixel regions 116. For example, in each of the pixel regions 116, the common lines 113 can be completely overlapping with the gate lines 111 for preventing a transparent area of the pixel region 116 from being sheltered by the common line 113. In this case, the material of the common lines 113 may be Al [symbol] Ag [symbol] Cu [symbol] Mo [symbol] Cr [symbol] W [symbol] Ta [symbol] Ti or alloys thereof. Moreover, a line width of each of the common lines 113 may be substantially larger than, less than or identical to a line width of each of the gate lines 111.

Referring to FIG. 2A and FIG. 2B again, the pixel electrodes 114 and the common electrodes 115 are formed on the first substrate 110, and the pixel electrodes 114 and the common electrodes 115 are in a similar shape (such as straight lines or curved lines) and arranged in an alternating manner, wherein the pixel electrodes 114 and the common electrodes 115 are in the same plane. The pixel electrodes 114 are electrically connected to the TFT 117, and the common electrodes 115 are electrically connected to the common lines 113. The pixel electrodes 114 and the common electrodes 115 are transparent electrodes and preferably made of electrically conductive and transparent material, such as ITO, IZO, AZO, GZO, TCO or ZnO.

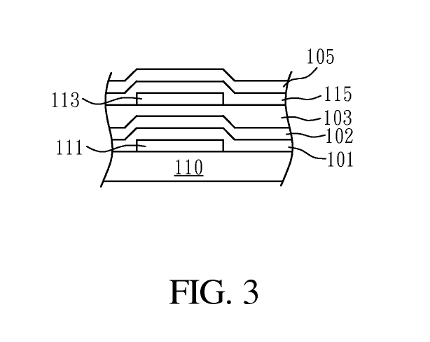

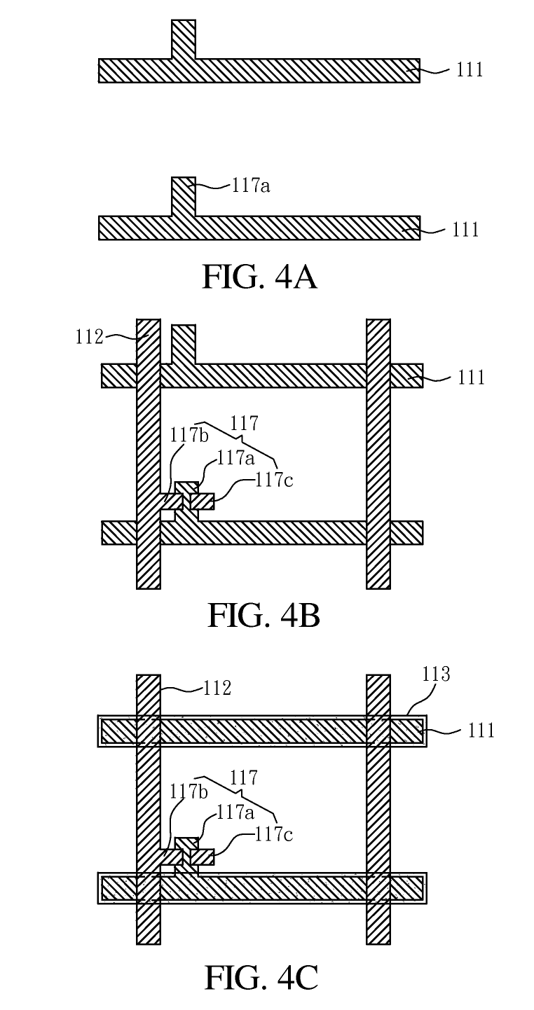

Referring to FIG. 2A, FIG. 3, FIG. 4A, FIG. 4B and FIG. 4C, FIG. 3 is a cross-sectional view along the cross-sectional line A-A′ shown in FIG. 2A, and FIG. 4A, FIG. 4B and FIG. 4C are schematic flow diagrams showing a process for manufacturing the IPS liquid crystal display panel according to the first embodiment of the present invention. Referring to FIG. 4A again, when manufacturing the IPS liquid crystal display panel 100, firstly, the gate lines 111 are formed on the first substrate 110, wherein portions of the gate lines 111 are the gate electrodes 117a of the TFTs 117.

Referring to FIG. 3 again, subsequently, a gate insulating layer 101 is formed on the gate lines 111, wherein the material of the gate insulating layer 101 may be silicon nitride (SiNₓ) or silicon oxide (SiOₓ) which may be formed with a plasma enhanced chemical vapor deposition (PECVD) method. Next, semiconductor islands (not shown) and an ohmic contact layer (not shown) of the TFTs 117 are formed on the gate insulating layer 101 in sequence. The semiconductor islands are preferably made of amorphous silicon (a-Si) or polycrystalline silicon. In this embodiment, when forming the semiconductor islands, an a-Si layer can be first deposited, and then a rapid thermal annealing (RTA) step is performed for the a-Si layer, thereby allowing the a-Si layer to recrystallize into a polycrystalline silicon layer. The material of the ohmic contact layer are preferably made of N+ a-Si (or silicide) heavily doped with N dopant (such as phosphorous) using such as ion implantation or chemical vapor deposition method.

Referring to FIG. 4B again, subsequently, the data lines 112 are formed on the gate insulating layer 101, and source electrodes 117b and drain electrodes 117c of the TFTs 117 are formed on the gate insulating layer 101. The material of the data lines 112, the source electrodes 117b and the drain electrodes 117c is preferably Mo [symbol] Al [symbol] Cr [symbol] Ta [symbol] Ti or alloys thereof, and may be a multi-layer structure with heat-resistant film and lower resistance film, such as dual-layer structure with molybdenum nitride film and Al film.

Referring to FIG. 3 again, subsequently, a passivation layer 102 and an over-coating layer 103 are formed on the data lines 112 and the TFTs 117 in sequence. Contact holes 104 are formed through the passivation layer 102 and the over-coating layer 103 to expose a portion of the drain electrodes 117b of the TFTs 117.

Referring to FIG. 4C again, subsequently, the common lines 113 are formed on the over-coating layer 103. In this case, the common lines 113 are positioned to the gate lines 111, and thus at least portions of the common lines 113 are positioned above the gate lines 111.

Referring to FIG. 2A again, subsequently, the pixel electrodes 114 and the common electrodes 115 are formed on the over-coating layer 103. The contact holes 104 are covered by portions of the pixel electrodes 114, and thus the pixel electrodes 114 can be electrically connected to the drain electrodes 117c of the TFTs 117, and further electrically connected to the gate lines 111. In this embodiment, each of the common electrodes 115 can directly cover and contact the common lines 113, thereby being electrically connected to common lines 113. Since the common electrodes 115 can directly cover and contact the common lines 113, through hole or contact window is unnecessary for connecting to the common electrodes 115 and the common lines 113, and the manufacturing process can be simplified.

Referring to FIG. 3 again, subsequently, an alignment layer 105 is formed on the pixel electrodes 114 and the common electrodes 115. Next, the liquid crystal layer 130 is formed between the first substrate 110 and the second substrate 120, thereby forming the IPS liquid crystal display panel 100.

Therefore, portions of the common lines 113 can be overlapping with or positioned above the gate lines 111, hence preventing the common lines 113 and the gate lines 111 from being positioned at the same plane, and increasing the transparent area of the pixel regions 116 to improve the aperture ratio thereof.

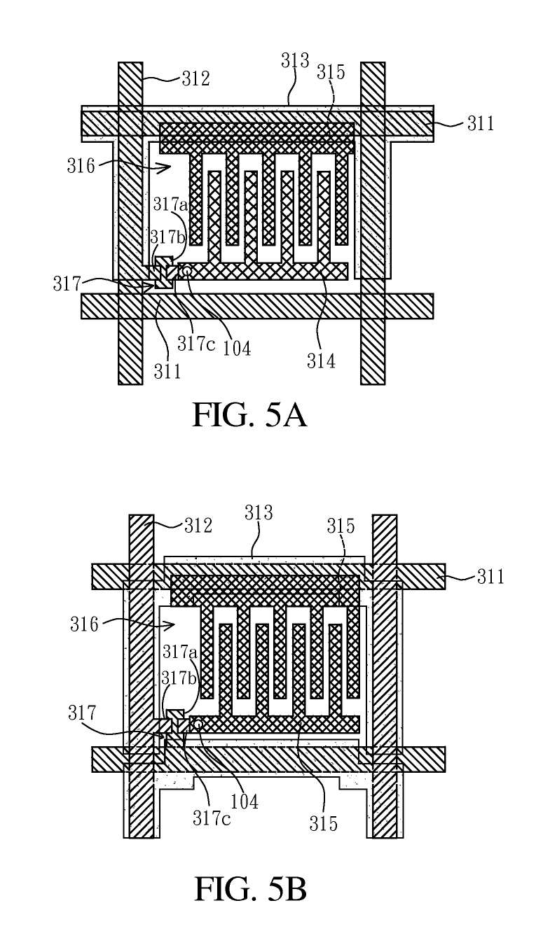

Referring to FIG. 5A and FIG. 5B, schematic diagrams showing a pixel region of the IPS liquid crystal display panel according to a second embodiment of the present invention are illustrated. The construction of the second embodiment is similar to that in the first embodiment with respect to configuration and function, and thus is not stated in detail herein. In comparison with the first embodiment, the IPS liquid crystal display panel of the second embodiment comprises a plurality of gate lines 311, a plurality of data lines 312, a plurality of common lines 313, a plurality of pixel electrodes 314 and a plurality of common electrodes 315. The pixel electrodes 314 are electrically connected to TFTs 317. The TFTs 317 comprise gate electrodes 317a, source electrodes 317b and drain electrodes 317c. In each of the pixel regions 316, the common lines 313 are further positioned above the gate lines 311 and the data lines 312. At this time, the opaque common lines 313 can act as a black matrix (BM) for improving a light leakage problem of the panel.

As described above, in comparison with the conventional IPS liquid crystal display panel having the gate lines and the common lines on the same plane, the common lines of the IPS liquid crystal display panel of the present invention can be positioned above the gate lines for increasing the transparent area of the pixels to improve the aperture ratio thereof. Moreover, the common lines of the present invention can act as the BM structure for improving the light leakage problem of the panel.

As is understood by a person skilled in the art, the foregoing embodiments of the present invention are strengths of the present invention rather than limiting of the present invention. It is intended to cover various modifications and similar arrangements included within the spirit and scope of the appended claims, the scope of which should be accorded the broadest interpretation so as to encompass all such modifications and similar structures.

What is claimed is:

1. An in-plane switching (IPS) liquid crystal display panel, comprising:
a first substrate;
a plurality of gate lines disposed on the first substrate;
a plurality of data lines disposed on the first substrate, wherein the data lines crisscross the gate lines to form a plurality of pixel regions, and the pixel regions include thin film transistors (TFTs) electrically connected to the gate lines and the data lines;
a plurality of common lines disposed on the first substrate, wherein at least one portion of each of the common lines is positioned above one of the gate lines;
a plurality of pixel electrodes formed on the first substrate and electrically connected to the TFTs;
a plurality of common electrodes formed on the first substrate and electrically connected to the common lines;
a second substrate; and
a liquid crystal layer formed between the first substrate and the second substrate.

2. The IPS liquid crystal display panel as claimed in claim 1, wherein, in each of the pixel regions, the common lines are completely overlapping with the gate lines.

3. The IPS liquid crystal display panel as claimed in claim 1, wherein, in each of the pixel regions, the common lines are overlapping with the gate lines and the data lines.

4. The IPS liquid crystal display panel as claimed in claim 1, wherein the common electrodes directly cover and contact the common lines.

5. The IPS liquid crystal display panel as claimed in claim 1, wherein a passivation layer is positioned between the gate lines and the common lines.

6. The IPS liquid crystal display panel as claimed in claim 1, wherein an over-coating layer is positioned on the passivation layer, and the common lines are positioned on the over-coating layer.

7. A method for manufacturing an in-plane switching (IPS) liquid crystal display panel, comprising the following steps:
forming a plurality of gate lines on a first substrate;
forming a plurality of data lines on the first substrate, wherein the gate lines and the data lines are crisscrossed to form a plurality of pixel regions arranged in an array, wherein the pixel regions include TFTs electrically connected to the gate lines and the data lines;
forming a plurality of common lines on the first substrate, wherein at least one portion of each of the common lines is positioned above one of the gate lines;
forming a plurality of pixel electrodes and a plurality of common electrodes formed on the first substrate, wherein the pixel electrodes are electrically connected to the TFTs, and the common electrodes are electrically connected to the common lines; and
forming a liquid crystal layer between the first substrate and a second substrate.

8. The method as claimed in claim 7, wherein, when forming the common lines, in each of the pixel regions, the common lines are completely overlapping with the gate lines.

9. The method as claimed in claim 7, wherein the plurality of pixel electrodes and the plurality of common electrodes are positioned on the same plane.

10. The method as claimed in claim 9, wherein the plurality of pixel electrodes and the plurality of common electrodes are transparent electrodes.

11. The method as claimed in claim 7, wherein when forming the common lines, in each of the pixel regions, the common lines are overlapping with the gate lines and the data lines.

12. The method as claimed in claim 7, wherein when forming the common electrodes, the common electrodes directly cover and contact the common lines.
